(19) United States
(12) Patent Application Publication
(10) Pub. No.: US 2020/0407843 A1
(43) Pub. Date: Dec. 31, 2020

(54) GAS BARRIER FILM

(71) Applicant: FUJIFILM Corporation, Tokyo (JP)

(72) Inventors: Yoshihiko MOCHIZUKI, Minamiashigara-shi (JP); Shinya SUZUKI, Minamiashigara-shi (JP)

(73) Assignee: FUJIFILM Corporation, Tokyo (JP)

(21) Appl. No.: 17/021,022

(22) Filed: Sep. 15, 2020

Related U.S. Application Data
(63) Continuation of application No. PCT/JP2019/008083, filed on Mar. 1, 2019.

(30) Foreign Application Priority Data
Mar. 28, 2018 (JP) 2018-062319

(51) Int. Cl. C23C 16/34; C23C 16/40; C23C 16/50

(52) U.S. Cl. CPC C23C 16/345; H01L 51/5253; C23C 16/50; C23C 16/401

(57) ABSTRACT

A gas barrier film includes a substrate, a silicon nitride layer, and a protective inorganic layer disposed on a surface side of the silicon nitride layer, which is opposite to a substrate side of the silicon nitride layer, in which the protective inorganic layer formed of silicon oxide, a thickness of the silicon nitride layer is 3 nm to 100 nm, and a ratio t₂/t₁ of a thickness t₂ of the protective inorganic layer to the thickness t₁ of the silicon nitride layer 3 to 80.

### CROSS-REFERENCE TO RELATED APPLICATIONS

This application is a Continuation of PCT International Application No. PCT/JP2019/008083 filed on Mar. 1, 2019, which claims priority under 35 U.S.C § 119(a) to Japanese Patent Application No. 2018-062319 filed on Mar. 28, 2018. Each of the above application(s) is hereby expressly incorporated by reference, in its entirety, into the present application.

### BACKGROUND OF THE INVENTION

### 1. Field of the Invention

The present invention relates to a gas barrier film.

### 2. Description of the Related Art

In recent years, high gas barrier performance is required for optical elements (optical devices) such as an organic electroluminescence (EL) element, a solar cell, a quantum dot film, and a display material, packaging materials such as an infusion bag containing a chemical agent which is altered by moisture or oxygen, and the like.

Therefore, necessary gas barrier performance is imparted to these members by sticking a gas barrier film, sealing with the gas barrier film, or the like.

The gas barrier film has, for example, a configuration obtained by forming a gas barrier layer formed of an inorganic material on a substrate.

For example, JP2013-230605A discloses a gas barrier film in which a laminated film including a silicon nitride film, and a silicon oxide film and/or a silicon oxynitride film is formed on one surface side of a base film having a thickness of 5 to 50 μm, and in which the residual stress of the entire laminated film is ±100 MPa.

### SUMMARY OF THE INVENTION

JP2013-230605A discloses that a film thickness ratio (A/B) of a film thickness A of the silicon nitride film to a film thickness B of the silicon oxide film and/or the silicon oxynitride film in the gas barrier film is 1 to 4, and the thickness of each layer is 20 nm to 500 nm.

In addition, JP2013-230605A discloses that, by having the silicon nitride film, and the silicon oxide film and/or the silicon oxynitride film, gas barrier property which cannot be achieved by each of these films alone is exhibited. That is, JP2013-230605A discloses that, by laminating a plurality of layers having gas barrier property, high gas barrier property can be obtained.

Here, as described above, the gas barrier film is used for sealing optical elements such as an organic EL element, a solar cell, a quantum dot film, and a display material. Therefore, high transparency is required for the gas barrier film.

However, according to the studies of the present inventors, it has been found that, in a case where the film thickness ratio (A/B) of the silicon nitride film to the silicon oxide film and/or the silicon oxynitride film, and the thickness of each film are within the above-described range, there is a problem that transparency is low. Specifically, by interference between light reflected at a boundary surface of the silicon oxide film and the silicon nitride film, and light reflected at a boundary surface of the silicon nitride film and a base layer or at a boundary surface of the silicon nitride film and a substrate, reflectance increases and transparency decreases.

In addition, in a case where the thickness of the silicon nitride film having high density is larger than that of the silicon oxide film and/or the silicon oxynitride film, bending resistance decreases. Therefore, in a case of bending the gas barrier film, there is a problem that the silicon nitride film is broken and gas barrier performance is deteriorated.

Furthermore, in the configuration in which each layer has barrier property, there is a problem that, in a case of bending the gas barrier film, barrier performance is deteriorated in a case where any one of the layers is broken.

An object of the present invention is to solve such problems, and is to provide a gas barrier film having high transparency and excellent bending resistance.

The object of the present invention is achieved by the following configurations.
[1] A gas barrier film comprising:
a substrate;
a silicon nitride layer; and
a protective inorganic layer disposed on a surface side of the silicon nitride layer, which is opposite to a substrate side of the silicon nitride layer,
in which the protective inorganic layer formed of silicon oxide,
a thickness of the silicon nitride layer is 3 nm to 100 nm, and
a ratio t₂/t₁ of a thickness t₂ of the protective inorganic layer to a thickness t₁ of the silicon nitride layer is 3 to 80.
[2] The gas barrier film according to [1],
in which a refractive index of the silicon nitride layer is higher than a refractive index of the protective inorganic layer.
[3] The gas barrier film according to [1] or [2],
in which a difference between a refractive index of the silicon nitride layer and a refractive index of the protective inorganic layer is 0.1 to 0.5.
[4] The gas barrier film according to any one of [1] to [3],
in which the thickness of the protective inorganic layer is 10 nm to 1000 nm.
[5] The gas barrier film according to any one of [1] to [4],
in which the thickness of the silicon nitride layer is 3 nm to 50 nm.
[6] The gas barrier film according to any one of [1] to [5],
in which a refractive index of the silicon nitride layer is 1.7 to 2.2.
[7] The gas barrier film according to any one of [1] to [6],
in which a refractive index of the protective inorganic layer is 1.3 to 1.6.
[8] The gas barrier film according to any one of [1] to [7], further comprising:
a base layer disposed on the substrate side of the silicon nitride layer.
[9] The gas barrier film according to [8],
in which the base layer formed of an inorganic material having a refractive index lower than that of the silicon nitride layer.
[10] The gas barrier film according to [8] or [9],
in which the base layer formed of silicon oxide.

According to the present invention, it is possible to provide a gas barrier film having high transparency and excellent bending resistance.

### BRIEF DESCRIPTION OF THE DRAWINGS

FIG. 1 is a view conceptually showing an example of a gas barrier film according to an embodiment of the present invention.

FIG. 2 is a view conceptually showing another example of the gas barrier film according to the embodiment of the present invention.

FIG. 3 is a view conceptually showing another example of the gas barrier film according to the embodiment of the present invention.

FIG. 4 is a view conceptually showing an example of an inorganic film forming apparatus for producing the gas barrier film according to the embodiment of the present invention.

### DESCRIPTION OF THE PREFERRED EMBODIMENTS

Hereinafter, the gas barrier film according to an embodiment of the present invention will be described with reference to the drawings.

The description of the constitutional requirements described below is made on the basis of representative embodiments of the present invention, but it should not be construed that the present invention is limited to those embodiments. In the drawings of the present specification, the scale of each part is appropriately changed and shown in order to facilitate visual recognition.

In this specification, numerical value ranges expressed by the term “to” mean that the numerical values described before and after “to” are included as a lower limit value and an upper limit value, respectively.

In the following description, “thickness” means a length in a direction (hereinafter, thickness direction) in which a substrate, silicon nitride layer, and protective inorganic layer described later are arranged.

[Gas Barrier Film]

The gas barrier film according to the embodiment of the present invention is a gas barrier film including a substrate, a silicon nitride layer, and a protective inorganic layer disposed on a surface side of the silicon nitride layer, which is opposite to a substrate side of the silicon nitride layer, in which the protective inorganic layer formed of silicon oxide, a thickness of the silicon nitride layer is 3 nm to 100 nm, and a ratio t₂/t₁ of a thickness t₂ of the protective inorganic layer to a thickness t₁ of the silicon nitride layer is 3 to 80.

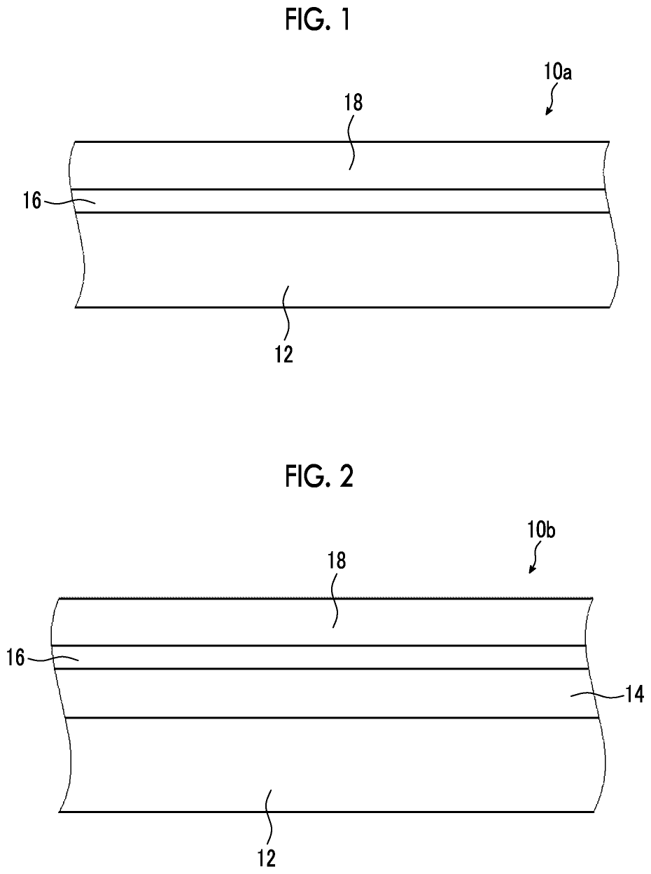

FIG. 1 conceptually shows an example of the gas barrier film according to the embodiment of the present invention.

FIG. 1 is a conceptual view of the gas barrier film according to the embodiment of the present invention viewed from a surface direction of a main surface. The main surface is the largest surface of a sheet-like material (film and plate-like material).

A gas barrier film 10a shown in FIG. 1 is composed of a substrate 12, a silicon nitride layer 16, and a protective inorganic layer 18.

In the following description, in the gas barrier film 10a, a side of the substrate 12 is also referred to as “bottom”, and a side of the protective inorganic layer 18 is also referred to as “top”.

As shown in FIG. 1, the silicon nitride layer 16 is located on a side closer to the substrate 12, and the protective inorganic layer 18 is located on a side farther from the substrate 12. That is, the protective inorganic layer 18 is located on a surface side of the silicon nitride layer 16, which is opposite to a side of the substrate 12. In the example shown in FIG. 1, the silicon nitride layer 16 is formed in contact with the substrate 12, and the protective inorganic layer 18 is formed in contact with the silicon nitride layer 16.

Here, in the gas barrier film 10a according to the embodiment of the present invention, the silicon nitride layer 16 is a layer which mainly exhibits gas barrier performance. Therefore, from the viewpoint of obtaining high gas barrier property, the thickness of the silicon nitride layer 16 is 3 nm or more. In addition, from the viewpoint of bending resistance, the thickness of the silicon nitride layer 16 is 100 nm or less.

In addition, in the present invention, the protective inorganic layer 18 is a silicon oxide film formed of silicon oxide (SiO). The protective inorganic layer 18 is a layer for protecting the silicon nitride layer 16. In a case where the thickness of the silicon nitride layer 16 is defined as t₁ and the thickness of the protective inorganic layer 18 is defined as t₂, the ratio t₂/t₁ of the thicknesses is 3 to 80. That is, the protective inorganic layer 18 is thicker than the silicon nitride layer 16.

As described above, in a case of the configuration in which the film thickness A of the silicon nitride film is larger than the film thickness B of the silicon oxide film and/or the silicon oxynitride film (ratio (A/B) is 1 to 4), and the thickness of each layer is 20 nm to 500 nm, there is a problem that transparency is low.

In addition, in a case where the thickness of the silicon nitride film having high density is larger than that of the silicon oxide film and/or the silicon oxynitride film, bending resistance decreases. Therefore, in a case of bending the gas barrier film, there is a problem that the silicon nitride film is broken and gas barrier performance is deteriorated.

Furthermore, in the configuration in which the silicon nitride film, and the silicon oxide film and/or the silicon oxynitride film have barrier property, there is a problem that, in a case of bending the gas barrier film, barrier performance is deteriorated in a case where any one of the layers is broken.

In addition, a gas barrier film in which a protective layer formed of an organic material is formed as a layer protecting inorganic barrier layers such as the silicon nitride film is also be used. However, in a case of incorporating such a gas barrier film into a device such as an organic EL, elements such as an organic EL may be damaged due to outgas generated from the protective layer. In addition, since the protective layer formed of an organic material is soft, it is necessary to increase the film thickness. However, in a case of increasing the film thickness, optical interference is likely to occur, and there is a problem that it is difficult to increase transparency.

On the other hand, the gas barrier film 10a according to the embodiment of the present invention has a configuration of including the silicon nitride layer 16, and the protective inorganic layer 18 formed of silicon oxide, in which the thickness of the silicon nitride layer is 3 nm to 100 nm, and the ratio t₂/t₁ of the thickness t₂ of the protective inorganic layer to the thickness t₁ of the silicon nitride layer is 3 to 80.

Since the gas barrier film according to the embodiment of the present invention has such a configuration, the reflection at the boundary surface of the silicon nitride layer 16 and the substrate 12, and the reflection at the boundary surface of the silicon nitride layer 16 and the protective inorganic layer 18 can be suppressed so as to increase transparency.

In addition, in the gas barrier film according to the embodiment of the present invention, by reducing the thickness of the silicon nitride layer 16 having high density, and protecting the silicon nitride layer 16 with the protective inorganic layer 18 which is thicker than the silicon nitride layer 16 and has low density, in a case of bending the gas barrier film, it is possible to suppress the silicon nitride layer 16 from being broken, and to obtain high bending resistance.

In addition, in the gas barrier film according to the embodiment of the present invention, since the silicon nitride layer 16 mainly secures gas barrier performance, the gas barrier performance is unlikely to deteriorate even in a case where other layers are broken.

In addition, in the gas barrier film according to the embodiment of the present invention, since the layer protecting the silicon nitride layer 16 is formed of silicon oxide which is an inorganic material, outgas is not generated. Therefore, in a case of incorporating such a gas barrier film into a device, it is possible to prevent elements such as an organic EL from being damaged due to outgas generated from the protective layer.

Here, from the viewpoint of transparency and bending resistance, the thickness of the silicon nitride layer 16 is preferably 3 nm to 50 nm, more preferably 4 nm to 45 nm, and still more preferably 5 nm to 40 nm.

In addition, the thickness of the protective inorganic layer 18 is preferably 10 nm to 1000 nm, more preferably 30 nm to 600 nm, and still more preferably 50 nm to 400 nm.

Here, from the viewpoint of transparency and bending resistance, the ratio t₂/t₁ of the thickness t₂ of the protective inorganic layer 18 to the thickness t₁ of the silicon nitride layer 16 is preferably 3 to 80, more preferably 4 to 50, and still more preferably 6 to 25.

The thicknesses of the silicon nitride layer 16 and the protective inorganic layer 18 can be measured by observing a cross section with a transmission electron microscope (TEM).

In addition, from the viewpoint of transparency, it is preferable that the refractive index of the silicon nitride layer 16 is higher than the refractive index of the protective inorganic layer 18 (silicon oxide film).

Here, in general, the silicon nitride film has a density higher than that of the silicon oxide film so as to have a higher refractive index. However, the silicon nitride film and the silicon oxide film include other elements such as hydrogen, oxygen, and carbon depending on film forming conditions, such as plasma CVD, in a case of forming a film. By adjusting the contents of these elements, the densities of the silicon nitride film and the silicon oxide film can be respectively adjusted. That is, the density of each of the silicon nitride film and the silicon oxide film can be adjusted by adjusting the film forming conditions. Therefore, the refractive index of the protective inorganic layer 18 (silicon oxide film) can be higher than the refractive index of the silicon nitride layer 16.

The contents of the other elements included in the silicon nitride film and the silicon oxide film can be respectively adjusted by adjusting the flow rate of raw material gas in a case of forming a film. In addition, the content of elements in the film can be adjusted by performing a hydrogen plasma treatment, an oxygen plasma treatment, or the like after forming the film.

From the viewpoint of transparency, the difference between the refractive index of the silicon nitride layer 16 and the refractive index of the protective inorganic layer 18 is preferably 0.1 or more, more preferably 0.1 to 0.5, and still more preferably 0.2 to 0.4.

In addition, the refractive index of the silicon nitride layer is preferably 1.7 to 2.2, more preferably 1.72 to 2.1, and still more preferably 1.75 to 2.05.

In addition, the refractive index of the protective inorganic layer is preferably 1.3 to 1.6, more preferably 1.3 to 1.57, and still more preferably 1.35 to 1.55.

The refractive index is measured using a spectroscopic ellipsometer UVISEL (manufactured by HORIBA, Ltd.). The refractive index is a value of a refractive index at a wavelength of 589.3 nm.

Here, the example shown in FIG. 1 has a configuration in which the silicon nitride layer 16 is directly laminated on the substrate 12, but the present invention is not limited to the example.

For example, a gas barrier film 10b shown in FIG. 2 has a substrate 12, a base layer 14, a silicon nitride layer 16, and a protective inorganic layer 18 in this order. That is, the gas barrier film 10b has the base layer 14, which is a base of the silicon nitride layer 16, between the substrate 12 and the silicon nitride layer 16 (on a substrate 12 side of the silicon nitride layer 16).

By having the base layer 14, irregularities on the surface of the substrate 12, foreign matters attached to the surface, and the like can be embedded so as to form a deposition surface of the silicon nitride layer 16 properly. As a result, it is possible to form a proper silicon nitride layer 16 having no breaking, crack, or the like on the entire deposition surface without any gap. Therefore, high gas barrier performance can be obtained. In addition, the base layer 14 acts as a cushion for the silicon nitride layer 16, and can suitably suppress the breaking of the silicon nitride layer 16.

The base layer 14 may be formed of an organic material or may be formed of an inorganic material.

From the viewpoint of transparency, the base layer 14 is preferably formed of an inorganic material which can be thinned, more preferably formed of an inorganic material having a refractive index lower than that of the silicon nitride layer 16, and still more preferably a silicon oxide film.

In addition, the gas barrier film according to the embodiment of the present invention may have a configuration in which two or more combinations of the base layer and the silicon nitride layer are included.

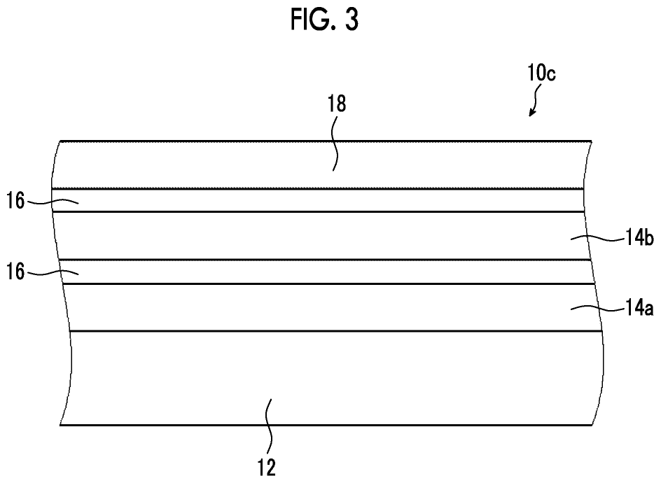

For example, a gas barrier film 10c shown in FIG. 3 has a substrate 12, a base layer 14a, a silicon nitride layer 16, a base layer 14b, a silicon nitride layer 16, and a protective inorganic layer 18 in this order.

The base layer 14a is a layer which is a base of the silicon nitride layer 16 on a side closer to the substrate 12, the base layer 14b is a layer which is a base of the silicon nitride layer 16 on a side farther from the substrate 12.

As described above, by having two or more combinations of the silicon nitride layer 16 and the base layer, gas barrier property can be further improved.

Next, each constitutional element of the gas barrier film will be described in detail. In the following description, in a case where it is not necessary to distinguish the gas barrier films 10a to 10c, the gas barrier films 10a to 10c are collectively referred to as the gas barrier film 10. In addition, in a case where it is not necessary to distinguish the base layer 14a and the base layer 14b, the base layer 14a and the base layer 14b are collectively referred to as the base layer 14.

<Substrate>

As the substrate 12, a known sheet-like material (film and plate-like material) which is used as a substrate (support) in various gas barrier films, various laminated functional films, and the like can be used.

The material of the substrate 12 is not limited, and various materials can be used as long as the base layer 14, the silicon nitride layer 16, and the protective inorganic layer 18 can be formed. As the material of the substrate 12, various resin materials are preferably exemplified.

Examples of the material of the substrate 12 include polyethylene (PE), polyethylene naphthalate (PEN), polyamide (PA), polyethylene terephthalate (PET), polyvinyl chloride (PVC), polyvinyl alcohol (PVA), polyacrylonitrile (PAN), polyimide (PI), transparent polyimide, polymethyl methacrylate resin (PMMA), polycarbonate (PC), polyacrylate, polymethacrylate, polypropylene (PP), polystyrene (PS), acrylonitrile-butadiene-styrene copolymer (ABS), cycloolefin copolymer (COC), cycloolefin polymer (COP), triacetyl cellulose (TAC), and ethylene-vinyl alcohol copolymer (EVOH).

The thickness of the substrate 12 can be appropriately set depending on the application, the material, and the like.

The thickness of the substrate 12 is not limited, but from the viewpoint that the mechanical strength of the gas barrier film 10 can be sufficiently secured, a gas barrier film having good flexibility can be obtained, the weight and thickness of the gas barrier film 10 can be reduced, a gas barrier film 10 having good flexibility can be obtained, and the like, is preferably 5 to 150 μm and more preferably 10 to 100 μm.

<Silicon Nitride Layer>

The silicon nitride layer 16 is a thin film including silicon nitride as a main component, and formed on at least the surface of the substrate 12 (or the base layer 14).

In the gas barrier film 10, the silicon nitride layer 16 mainly exhibits gas barrier performance.

The surface of the substrate 12 may have a region where an inorganic compound is difficult to deposit to form a film, such as irregularities and shadows of foreign matters. As described above, by providing the base layer 14 on the surface of the substrate 12 and forming the silicon nitride layer 16 thereon, the region where an inorganic compound is difficult to deposit to form a film is covered. Therefore, it is possible to form the silicon nitride layer 16 on the surface of forming the silicon nitride layer 16 without any gap. In the present specification, the main component refers to a component having the largest content mass ratio among the contained components.

Silicon nitride, which is the material of the silicon nitride layer 16, has high transparency and can exhibit excellent gas barrier performance.

The silicon nitride layer 16 may include elements such as hydrogen and oxygen.

The content of hydrogen in the silicon nitride layer 16 is preferably 10 atom % to 50 atom %, more preferably 15 atom % to 45 atom %, and still more preferably 20 atom % to 40 atom %. As the content of hydrogen is lower, the density of the silicon nitride layer is higher. Therefore, in a case where the content of hydrogen is 10 atom % or more, bending resistance can be improved, and in a case where the content of hydrogen is 50 atom % or less, gas barrier property can be enhanced.

In addition, the silicon nitride layer 16 preferably contains a small amount of oxygen element, and more preferably does not contain oxygen element. The content of oxygen in the silicon nitride layer 16 is preferably 0 atom % to 10 atom %, more preferably 0 atom % to 8 atom %, and still more preferably 0 atom % to 5 atom %. As the content of oxygen is lower, the density of the silicon nitride layer is higher. Therefore, in a case where the content of oxygen is 10 atom % or less, gas barrier property can be enhanced.

As an example shown in FIG. 3, in a case where a plurality of the silicon nitride layers 16 is provided, the thickness of each silicon nitride layer 16 may be the same as or different from each other.

The silicon nitride layer 16 can be formed by a known method depending on the material.

Suitable examples of the method include various vapor deposition methods such as plasma CVD, for example, capacitively coupled plasma (CCP)-CVD, inductively coupled plasma (ICP)-CVD, and the like; atomic layer deposition (ALD); sputtering, for example, magnetron sputtering, reactive sputtering, and the like; and vacuum vapor deposition.

Among these, plasma CVD such as CCP-CVD and ICP-CVD is suitably used from the viewpoint that the adhesive force between the substrate 12 (base layer 14) and the silicon nitride layer 16 can be improved.

<Protective Inorganic Layer>

The protective inorganic layer 18 is a thin film including silicon oxide as a main component, and formed on the surface of the silicon nitride layer 16.

In the gas barrier film 10, since the protective inorganic layer 18 protects the silicon nitride layer 16 which exhibits gas barrier performance, in a case of bending the gas barrier film 10, the protective inorganic layer 18 suppresses the breaking of the silicon nitride layer 16 and maintains high gas barrier performance.

Silicon oxide, which is the material of the protective inorganic layer 18, has high transparency. In addition, since the silicon oxide film basically has a density lower than that of the silicon nitride film, the protective inorganic layer 18 is flexible and can protect the silicon nitride layer.

The silicon oxide film which is the protective inorganic layer 18 may include elements such as hydrogen and carbon.

The content of carbon in the silicon oxide film is preferably 2 atom % to 20 atom %, more preferably 3 atom % to 18 atom %, and still more preferably 5 atom % to 15 atom %. As the content of carbon is higher, the density of the silicon oxide film is lower and bending resistance is more improved. On the other hand, as the content of carbon is lower, transparency is improved.

The protective inorganic layer 18 can be formed by a known method depending on the material.

Suitable examples of the method include various vapor deposition methods such as plasma CVD, for example, capacitively coupled plasma (CCP)-CVD, inductively coupled plasma (ICP)-CVD, and the like; atomic layer deposition (ALD); sputtering, for example, magnetron sputtering, reactive sputtering, and the like; and vacuum vapor deposition.

Among these, plasma CVD such as CCP-CVD and ICP-CVD is suitably used from the viewpoint that the adhesive force between the silicon nitride layer 16 and the protective inorganic layer 18 can be improved.

Composition of a film (composition of the silicon nitride layer and composition of the protective inorganic layer) can be measured according to Rutherford backscattering spectrometry (RBS) measurement using a high-resolution RBS system HRBS-V500 (manufactured by KOBE STEEL, LTD.) and hydrogen forwardscattering spectrometry (HFS) measurement.

<Base Layer>

The base layer 14 is a layer which is a base of the silicon nitride layer 16, and is a layer in which irregularities on the surface of the substrate 12, foreign matters attached to the surface, and the like are embedded so as to form the deposition surface of the silicon nitride layer 16 properly and form a proper silicon nitride layer 16 having no breaking, crack, or the like. In addition, the base layer 14 acts as a cushion for the silicon nitride layer 16, and can suitably suppress the breaking of the silicon nitride layer 16.

The base layer 14 may be an organic base layer formed of an organic material, or an inorganic base layer formed of an inorganic material.

From the viewpoint of foreign matter embedding property, an organic base layer is preferable. On the other hand, from the viewpoint of etching resistance in a case of forming the silicon nitride layer, an inorganic base layer is preferable.

(Organic Base Layer)

The organic base layer is, for example, a layer formed of an organic compound obtained by polymerizing (crosslinking and curing) a monomer, a dimer, an oligomer, and the like.

The organic base layer is formed, for example, by curing a composition for forming an organic base layer, which contains an organic compound (monomer, dimer, trimer, oligomer, polymer, and the like). The composition for forming an organic base layer may include one kind of organic compound, or may include two or more kinds thereof.

The organic base layer contains, for example, a thermoplastic resin, an organosilicon compound, and the like. Examples of the thermoplastic resin include polyester, (meth)acrylic resin, methacrylic acid-maleic acid copolymer, polystyrene, transparent fluororesin, polyimide, fluorinated polyimide, polyamide, polyamideimide, polyetherimide, cellulose acylate, polyurethane, polyetheretherketone, polycarbonate, alicyclic polyolefin, polyarylate, polyethersulfone, polysulfone, fluorene ring-modified polycarbonate, alicyclic-modified polycarbonate, fluorene ring-modified polyester, and acrylic compound. Examples of the organosilicon compound include polysiloxane.

From the viewpoint of excellent strength and viewpoint of glass transition point, the organic base layer preferably includes a polymerization product of a radically curable compound and/or a cationic curable compound having an ether group.

From the viewpoint of lowering refractive index of the organic base layer, the organic base layer preferably includes a (meth)acrylic resin having a polymer of a monomer, oligomer, and the like of (meth)acrylate as a main component. By lowering the refractive index of the organic base layer, transparency increases and light-transmitting property is improved.

The organic base layer more preferably includes a (meth)acrylic resin having, as a main component, a polymer of a monomer, dimer, oligomer, and the like of bi- or more functional (meth)acrylate, such as dipropylene glycol di(meth)acrylate (DPGDA), trimethylolpropane tri(meth)acrylate (TMPTA), and dipentaerythritol hexa(meth)acrylate (DPHA), and still more preferably include a (meth)acrylic resin having a polymer of a monomer, dimer, oligomer, and the like of tri- or more functional (meth)acrylate as a main component. In addition, a plurality of these (meth)acrylic resins may be used.

The composition for forming an organic base layer preferably includes an organic solvent, a surfactant, a silane coupling agent, and the like, in addition to the organic compound.

In a case where a plurality of organic base layers is provided, that is, a case where a plurality of sets of a combination of the organic base layer and the silicon nitride layer 16 is provided, the material of each organic base layer may be the same as or different from each other.

The thickness of the organic base layer is not limited, and can be appropriately set depending on the components included in the composition for forming an organic base layer, the substrate 12 to be used, and the like.

The thickness of the organic base layer is preferably 0.1 to 5 μm and more preferably 0.2 to 3 μm. The aspect in which the thickness of the organic base layer is 0.1 μm or more is preferable from the viewpoint that the surface of the organic base layer can be flattened by embedding irregularities on the surface of the substrate 12, foreign matters attached to the surface, and the like. The aspect in which the thickness of the organic base layer is 5 μm or less is preferable from the viewpoint that cracks in the organic base layer can be prevented, flexibility of the gas barrier film 10 can be increased, the weight and thickness of the gas barrier film 10 can be reduced, and the like.

In a case where a plurality of organic base layers is provided, that is, a case where a plurality of sets of a combination of the silicon nitride layer 16 and the organic base layer is provided, the thickness of each organic base layer may be the same as or different from each other. With regard to this point, the same applies to the silicon nitride layer 16.

The organic base layer can be formed by a known method depending on the material.

For example, the organic base layer can be formed according to a coating method in which the above-described composition for forming an organic base layer is applied and dried. In the formation of the organic base layer according to the coating method, the dried composition for forming an organic base layer is further irradiated with ultraviolet rays to polymerize (crosslink) the organic compound in the composition as necessary.

(Inorganic Base Layer)

The inorganic base layer is a layer formed of an inorganic material having a refractive index lower than that of the silicon nitride layer 16.

As the inorganic base layer, various films which have a refractive index lower than that of the silicon nitride layer 16, have high transparency, and are formed of a material having good adhesiveness to the substrate 12 and the silicon nitride layer 16 can be used. For example, a silicon oxide film, a silicon oxynitride film, an aluminum oxide film, or the like can be used.

In particular, from the viewpoint that transparency is high and various materials and film forming methods can be used, a silicon oxide film is suitably exemplified.

The thickness of the inorganic base layer can be appropriately set depending on the material of the inorganic base layer, the substrate 12, and the like.

The thickness of the inorganic base layer is preferably 5 nm to 800 nm, more preferably 10 nm to 700 nm, and still more preferably 20 nm to 600 nm.

The aspect in which the thickness of the inorganic base layer is 5 nm or more is preferable from the viewpoint that it is possible to prevent damage in a case of forming the silicon nitride layer by covering a surface of a base material, it is possible to suppress the occurrence of defects in the silicon nitride layer by covering irregularities of the base material, and the like. The aspect in which the thickness of the inorganic base layer is 800 nm or less is preferable from the viewpoint that transparency can be increased, cracks in the inorganic base layer can be prevented, flexibility of the gas barrier film can be increased, and the like.

In a case where a plurality of inorganic base layers is provided, that is, a case where a plurality of sets of a combination of the silicon nitride layer 16 and the inorganic base layer is provided, the thickness of each inorganic base layer may be the same as or different from each other.

The inorganic base layer can be formed by a known method depending on the material.

In the inorganic base layer, suitable examples of the method include various vapor deposition methods such as plasma CVD, for example, capacitively coupled plasma (CCP)-CVD, inductively coupled plasma (ICP)-CVD, and the like; atomic layer deposition (ALD); sputtering, for example, magnetron sputtering, reactive sputtering, and the like; and vacuum vapor deposition.

Alternatively, the inorganic base layer may be formed by coating. As the formation by coating, for example, a silicon oxide layer can be formed by coating perhydropolysilazane (PHPS) and reacting perhydropolysilazane with oxygen.

Among these, plasma CVD such as CCP-CVD and ICP-CVD is suitably used from the viewpoint that the adhesive force between the substrate 12 and the inorganic base layer can be improved.

[Method for Producing Gas Barrier Film]

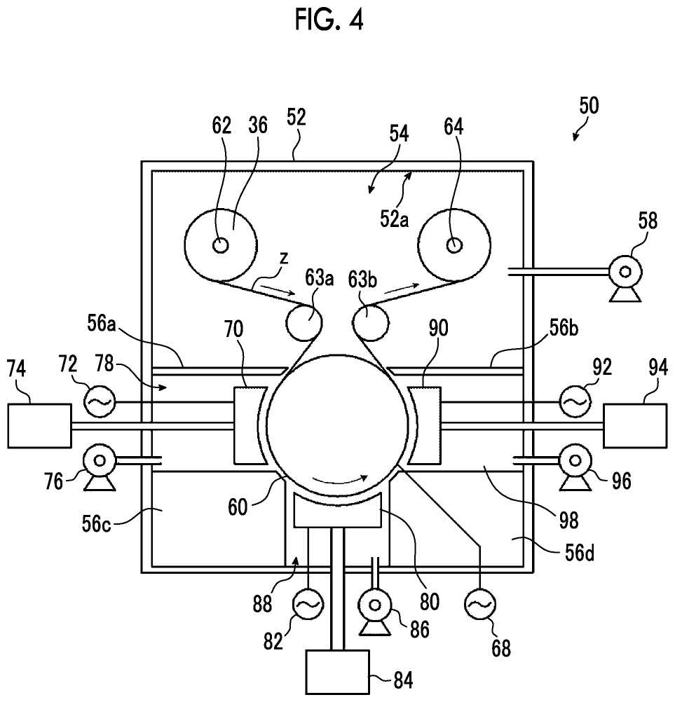

Hereinafter, an example of a method for producing the gas barrier film 10 according to the embodiment of the present invention will be described with reference to the conceptual view of FIG. 4.

An apparatus shown in FIG. 4 is basically a known roll-to-roll film forming apparatus according to plasma CVD. Hereinafter, using the apparatus shown in FIG. 4, a case of producing the gas barrier film 10b as shown in FIG. 2, which has a base layer 14 and in which the base layer 14 is an inorganic base layer 14, will be described.

A film forming apparatus 50 shown in FIG. 4 is an apparatus for producing a gas barrier film by, while transporting the substrate 12, which is an object Z to be treated, in a longitudinal direction, sequentially forming the inorganic base layer 14, the silicon nitride layer 16, and the protective inorganic layer 18 on a surface of the object Z to be treated according to plasma CVD.

In addition, the film forming apparatus 50 is an apparatus for forming a film by so-called roll-to-roll (hereinafter, also referred to as RtoR), in which an object Z to be treated is sent out from a laminate roll 36 formed by winding a long object Z (substrate 12) to be treated in a roll shape, the inorganic base layer 14, the silicon nitride layer 16, and the protective inorganic layer 18 are formed while transporting the object Z to be treated in a longitudinal direction, and the produced gas barrier film is wound in a roll shape.

The film forming apparatus 50 shown in FIG. 4 is an apparatus capable of forming a film on the object Z to be treated according to capacitively coupled plasma (CCP)-CVD, and is composed of a vacuum chamber 52, and an unwinding section 54, three film forming sections (first film forming section 78, second film forming section 88, and third film forming section 98), and a drum 60, which are formed in the vacuum chamber 52.

That is, the film forming apparatus 50 is an apparatus which has three film forming sections in the transport path of the object Z to be treated, and in which the inorganic base layer 14, the silicon nitride layer 16, and the protective inorganic layer 18 are respectively formed in the three film forming sections.

In the film forming apparatus 50, the long object Z to be treated is supplied from the laminate roll 36 of the unwinding section 54. Next, while transporting the long object Z to be treated, which is in a state of being wound around the drum 60, in the longitudinal direction, the inorganic base layer 14 is formed in the film forming section 78, the silicon nitride layer 16 is formed on the long object Z to be treated in the film forming section 88, and the protective inorganic layer 18 is formed on the long object Z to be treated in the film forming section 98. Thereafter, the long object Z to be treated is transported to the unwinding section 54 again, and wound up on a winding shaft 64 in the unwinding section 54.

The drum 60 is a cylindrical member, and rotates counterclockwise around an axis, as a rotating shaft, passing through the center of the circle and perpendicular to the drawing sheet.

The drum 60 winds the object Z to be treated, which is guided by a guide roller 63a of the unwinding section 54 described later in a predetermined path, around a predetermined region of a peripheral surface, transports the object Z to be treated in the longitudinal direction while holding the object Z to be treated at a predetermined position, sequentially transports the object Z to be treated to the film forming section 78, the film forming section 88, and the film forming section 98, and sends the object Z to be treated to a guide roller 63b of the unwinding section 54.

Here, the drum 60 also acts as a counter electrode of film forming electrodes of respective film forming sections described later. That is, the drum 60 and each film forming electrode form an electrode pair.

In addition, a bias power supply 68 is connected to the drum 60.

The bias power supply 68 is a power supply which supplies bias power to the drum 60.

The bias power supply 68 is basically a known bias power supply used in various plasma CVD apparatuses.

The unwinding section 54 is composed of an inner wall surface 52a of the vacuum chamber 52, a peripheral surface of the drum 60, and partition walls 56a and 56b extending from the inner wall surface 52a to the vicinity of the peripheral surface of the drum 60.

The unwinding section 54 has the above-described winding shaft 64, guide rollers 63a and 63b, a rotating shaft 62, and a vacuum exhaust unit 58.

The guide rollers 63a and 63b are normal guide rollers which guide the object Z to be treated along a predetermined transport path. In addition, the winding shaft 64 is a known long winding shaft which winds up the film-formed object Z to be treated.

In the illustrated example, the laminate roll 36, which is formed by winding the long object Z to be treated in a roll shape, is mounted in the rotating shaft 62. In addition, in a case where the laminate roll 36 is mounted in the rotating shaft 62, the object Z to be treated is passed through a predetermined path, through the guide roller 63a, drum 60, and guide roller 63b, thereby reaching the winding shaft 64.

The vacuum exhaust unit 58 is a vacuum pump for reducing the pressure in the unwinding section 54 to a predetermined degree of vacuum. The vacuum exhaust unit 58 sets the pressure in the unwinding section 54 to a pressure which does not affect the pressure in the film forming section 78, the film forming section 88, and the film forming section 98.

In the transport direction of the object Z to be treated, the film forming section 78 is disposed downstream of the unwinding section 54.

The film forming section 78 is composed of the inner wall surface 52a, the peripheral surface of the drum 60, and partition walls 56a and 56c extending from the inner wall surface 52a to the vicinity of the peripheral surface of the drum 60.

In the film forming apparatus 50, a film of the inorganic base layer 14 is formed on the surface of the object Z to be treated according to capacitively coupled plasma (CCP)-CVD in the film forming section 78. The film forming section 78 has a film forming electrode 70, a raw material gas supply unit 74, and a high-frequency power supply 72, and a vacuum exhaust unit 76.

The film forming electrode 70 is an electrode which constitutes, in the film forming apparatus 50, an electrode pair together with the drum 60 in a case of forming a film according to CCP-CVD. The film forming electrode 70 is disposed such that an electric discharge surface, which is one largest surface, faces the peripheral surface of the drum 60. The film forming electrode 70 generates plasma for forming a film between the electric discharge surface and the peripheral surface of the drum 60 forming the electrode pair, thereby forming a film forming region.

In addition, the film forming electrode 70 may be a so-called shower electrode in which a large number of through holes are entirely formed on the electric discharge surface.

The raw material gas supply unit 74 is a known gas supply unit used in a vacuum film forming apparatus such as a plasma CVD apparatus, and supplies a raw material gas into the film forming electrode 70. It is sufficient that the raw material gas supplied by the raw material gas supply unit 74 is appropriately selected according to the forming material of an inorganic base layer 14 to be formed.

The high-frequency power supply 72 is a power supply which supplies plasma excitation power to the film forming electrode 70. As the high-frequency power supply 72, all known high-frequency power supplies used in various plasma CVD apparatuses can also be used.

Furthermore, the vacuum exhaust unit 76 is a known vacuum exhaust unit which is used in a vacuum film forming apparatus and in which the inside of the film forming section 78 is exhausted to maintain a predetermined film forming pressure in order to form a gas barrier film according to plasma CVD.

As described above, it is sufficient that the method for forming the inorganic base layer 14 is performed, depending on the inorganic base layer 14 to be formed, according to a known vapor deposition method such as plasma CVD, for example, CCP-CVD, ICP-CVD, and the like; sputtering, for example, magnetron sputtering, reactive sputtering, and the like; and vacuum vapor deposition. Among these, as described above, plasma CVD such as CCP-CVD is suitably used in the formation of the inorganic base layer 14. Therefore, it is sufficient that the process gas to be used, the film forming conditions, and the like are appropriately set and selected depending on the material and film thickness of the inorganic base layer 14 to be formed, and the like.

The object Z to be treated, in which the inorganic base layer 14 is formed on the surface of the substrate 12 in the film forming section 78, is transported to the film forming section 88 disposed downstream of the film forming section 78.

The film forming section 88 is composed of the inner wall surface 52a, the peripheral surface of the drum 60, and partition walls 56c and 56d extending from the inner wall surface 52a to the vicinity of the peripheral surface of the drum 60.

In the film forming apparatus 50, a film of the silicon nitride layer 16 is formed on the surface of the object Z to be treated, that is, on the inorganic base layer 14 according to capacitively coupled plasma (CCP)-CVD in the film forming section 88. The film forming section 88 has a film forming electrode 80, a raw material gas supply unit 84, and a high-frequency power supply 82, and a vacuum exhaust unit 86.

The film forming electrode 80, the raw material gas supply unit 84, the high-frequency power supply 82, and the vacuum exhaust unit 86 are respectively the same as the film forming electrode 70, the raw material gas supply unit 74, the high-frequency power supply 72, and the vacuum exhaust unit 76 in the film forming section 78.

As described above, it is sufficient that the method for forming the silicon nitride layer 16 is performed, depending on the silicon nitride layer 16 to be formed, according to a known vapor deposition method such as plasma CVD, for example, CCP-CVD, ICP-CVD, and the like; sputtering, for example, magnetron sputtering, reactive sputtering, and the like; and vacuum vapor deposition. Among these, as described above, plasma CVD such as CCP-CVD is suitably used in the formation of the silicon nitride layer 16. Therefore, it is sufficient that the process gas to be used, the film forming conditions, and the like is appropriately set and selected depending on the material and film thickness of the silicon nitride layer 16 to be formed, and the like.

The object Z to be treated, in which the silicon nitride layer 16 is formed on the inorganic base layer 14 in the film forming section 88, is transported to the film forming section 98 disposed downstream of the film forming section 88.

The film forming section 98 is composed of the inner wall surface 52a, the peripheral surface of the drum 60, and partition walls 56d and 56b extending from the inner wall surface 52a to the vicinity of the peripheral surface of the drum 60.

In the film forming apparatus 50, a film of the protective inorganic layer 18 is formed on the surface of the object Z to be treated, that is, on the silicon nitride layer 16 according to capacitively coupled plasma (CCP)-CVD in the film forming section 98. The film forming section 98 has a film forming electrode 90, a raw material gas supply unit 94, and a high-frequency power supply 92, and a vacuum exhaust unit 96.

The film forming electrode 90, the raw material gas supply unit 94, the high-frequency power supply 92, and the vacuum exhaust unit 96 are respectively the same as the film forming electrode 70, the raw material gas supply unit 74, the high-frequency power supply 72, and the vacuum exhaust unit 76 in the film forming section 78.

As described above, it is sufficient that the method for forming the protective inorganic layer 18 is performed, depending on the protective inorganic layer 18 to be formed, according to a known vapor deposition method such as plasma CVD, for example, CCP-CVD, ICP-CVD, and the like; sputtering, for example, magnetron sputtering, reactive sputtering, and the like; and vacuum vapor deposition. Among these, as described above, plasma CVD such as CCP-CVD is suitably used in the formation of the protective inorganic layer 18. Therefore, it is sufficient that the process gas to be used, the film forming conditions, and the like is appropriately set and selected depending on the material and film thickness of the protective inorganic layer 18 to be formed, and the like.

The object Z to be treated in which the protective inorganic layer 18 is formed in the film forming section 98, that is, the gas barrier film 10 according to the embodiment of the present invention is transported into the unwinding section 54, guided by the guide roller 63b along a predetermined path, reaches the winding shaft 64, and wound around the winding shaft 64.

In the above-described method for producing a gas barrier film, all the layers are formed by RtoR in one film forming apparatus as a preferred aspect, but the method may include an aspect in which at least one step is performed by another film forming apparatus. In addition, the method may include an aspect in which at least one step may be performed batchwise, or all the steps may be performed batchwise with cut sheets.

In addition, as the example shown in FIG. 3, in a case where two or more combinations of the base layer 14 and the silicon nitride layer 16 are included, a film forming apparatus having film forming sections corresponding to the number of layers to be formed may be used, or at least one step may be performed by another film forming apparatus.

In addition, in the above-described method for producing a gas barrier film, the case where the base layer 14 is an inorganic base layer has been described. However, in a case where the base layer 14 is an organic base layer, it is sufficient that a substrate 12 having an organic base layer formed in advance on the surface thereof is used as the object Z to be treated, and the silicon nitride layer 16 and the protective inorganic layer 18 are formed in the same manner as described above.

Here, in a case where the film formation is performed by a plurality of apparatuses, such as a case where the base layer 14 is an organic base layer, a step of, in a case of moving the object Z to be treated to another apparatus, adhering a protective film to protect the formed layer and peeling off the protective film in a case of forming next layer is necessary.

On the other hand, in a case where the base layer 14 is an inorganic base layer, all layers can be formed in one film forming apparatus. Therefore, the step of adhering and peeling off the protective film is not necessary, which is suitable from the viewpoint of simplification of steps, no pressure sensitive adhesive residue of the protective film, and cost.

Hereinbefore, the gas barrier film according to the embodiment of the present invention has been described in detail, but the present invention is not limited to the above-described aspects and various improvements and changes can be made without departing from the spirit of the present invention.

For example, in the above-described method for producing a gas barrier film, all the layers are formed by RtoR as a preferred aspect, but at least one step may be performed batchwise after cutting the film, or all the steps may be performed batchwise with cut sheets.

### EXAMPLES

Hereinafter, the present invention will be described in more detail with reference to Examples. The present invention is not limited to the following specific examples.

### Example 1

As a substrate, a PET film manufactured by TOYOBO Co., Ltd., COSMOSHINE A4300; refractive index: 1.54) having a thickness of 100 μm and a width of 1000 mm was prepared.

<Formation of Base Layer>

The substrate (PET film) was coated with a material according to a coating method using a general coating apparatus, dried, and irradiated with ultraviolet rays to perform polymerization to form an organic base layer having a thickness of 100 nm (0.1 μm).

As a coating solution for forming the organic base layer, 1.4 g of TMPTA (manufactured by DAICEL-ALLNEX LTD.) as a polymerizable compound and ultraviolet polymerization initiator (manufactured by Lamberti S.P.A., ESACURE KTO46) was weighed such that the mass ratio was 95:5, and dissolved in methyl ethyl ketone to prepare a coating solution having a concentration of solid contents of 15%.

The prepared polymerizable composition was applied onto the substrate by RtoR using a die coater, passed through a drying zone at 50° C. over 3 minutes, and UV-cured by irradiating ultraviolet rays (total irradiation dose: approximately 600 mJ/cm²) to form the organic base layer.

As a protective film for an organic layer, PE (PAC2-30-T manufactured by Sun A. Kaken Co., Ltd.) was attached to the organic base layer in a pass roll immediately after forming the organic base layer, and the organic base layer was transported and wound.

<Formation of Silicon Nitride Layer and Protective Inorganic Layer>

Next, using an apparatus, as shown in FIG. 4, having three film forming sections for forming a film according to CCP-CVD by RtoR, the substrate on which the organic base layer was formed was used as an object Z to be treated, and a silicon nitride layer and a protective inorganic layer were formed on the object Z to be treated to produce a gas barrier film.

In Examples 1 to 12, the silicon nitride layer and the protective inorganic layer were formed using two of the three film forming sections.

The transport speed of the object Z to be treated was set to 2 m/min.

A bias power of 0.5 kW at a frequency of 0.4 MHz and was applied to a drum.

In addition, the protective film for an organic layer was peeled off before forming the silicon nitride layer.

(Silicon Nitride Layer Forming Step)

As a raw material gas for forming the silicon nitride layer, silane gas (SiH₄), ammonia gas (NH₃), and hydrogen gas (H₂) were used. The gas supply amount was 200 sccm for silane gas, 600 sccm for ammonia gas, and 1000 sccm for hydrogen gas. In addition, the film forming pressure was set to 100 Pa. The plasma excitation power was set to 2.5 kW at a frequency of 13.56 MHz.

The flow rate expressed in unit of sccm is a value converted into a flow rate (cc/min) at 1013 hPa and 0° C.

The thickness of the formed silicon nitride layer was 10 nm.

In addition, the refractive index of the silicon nitride layer was 1.8.

(Protective Inorganic Layer Forming Step)

As a raw material gas for forming the protective inorganic layer, hexamethyldisiloxane (HMDSO) gas represented by the following structural formula, and oxygen gas (O₂) were used. The gas supply amount was 400 sccm for HMDSO and 600 sccm for oxygen gas. In addition, the film forming pressure was set to 100 Pa. The plasma excitation power was set to 4 kW at a frequency of 13.56 MHz. That is, the protective inorganic layer is a silicon oxide film.

The thickness of the formed protective inorganic layer was 80 nm.

In addition, the refractive index of the protective inorganic layer was 1.48.

Therefore, the ratio t₂/t₁ of the thickness t₂ of the protective inorganic layer to the thickness t₁ of the silicon nitride layer was 8.0. In addition, the difference in refractive index between the silicon nitride layer and the protective inorganic layer was 0.32.

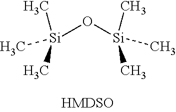

### Example 2

A gas barrier film was produced in the same manner as in Example 1, except that PET film (manufactured by TOYOBO Co., Ltd., COSMOSHINE A4100; refractive index: 1.54) was used as a substrate and no base layer was provided.

The silicon nitride layer was formed on a surface of the substrate on a side not having an easily adhesive layer.

### Example 3

A gas barrier film was produced in the same manner as in Example 1, except that, in the silicon nitride layer forming step, the supply amount of silane gas was set to 100 sccm, the supply amount of ammonia gas was set to 300 sccm, the supply amount of hydrogen gas was set to 1000 sccm, and the plasma excitation power was set to 1.5 kW.

The thickness of the formed silicon nitride layer was 6 nm. Therefore, the ratio t₂/t₁ of the thickness t₂ of the protective inorganic layer to the thickness t₁ of the silicon nitride layer was 13.3.

### Example 4

A gas barrier film was produced in the same manner as in Example 3, except that the transport speed of the object Z to be treated in a case of forming the silicon nitride layer and the protective inorganic layer was set to 1 m/min.

The thickness of the formed silicon nitride layer was 10 nm. In addition, the thickness of the formed protective inorganic layer was 140 nm. Therefore, the ratio t₂/t₁ of the thickness t₂ of the protective inorganic layer to the thickness t₁ of the silicon nitride layer was 14.0.

### Example 5

A gas barrier film was produced in the same manner as in Example 4, except that, in the protective inorganic layer forming step, the supply amount of HMDSO was set to 600 sccm, the supply amount of oxygen gas was set to 900 sccm, and the plasma excitation power was set to 5.5 kW.

The thickness of the formed protective inorganic layer was 240 nm. Therefore, the ratio t₂/t₁ of the thickness t₂ of the protective inorganic layer to the thickness t₁ of the silicon nitride layer was 24.0.

### Example 6

A gas barrier film was produced in the same manner as in Example 5, except that the transport speed was set to 0.5 m/min, and in the silicon nitride layer forming step, the supply amount of silane gas was set to 25 sccm, the supply amount of ammonia gas was set to 75 sccm, the supply amount of hydrogen gas was set to 1000 sccm, and the plasma excitation power was set to 0.5 kW.

The thickness of the formed silicon nitride layer was 6 nm. In addition, the thickness of the formed protective inorganic layer was 450 nm. Therefore, the ratio t₂/t₁ of the thickness t₂ of the protective inorganic layer to the thickness t₁ of the silicon nitride layer was 75.0.

### Example 7

A gas barrier film was produced in the same manner as in Example 1, except that, in the protective inorganic layer forming step, the supply amount of HMDSO was set to 200 sccm, the supply amount of oxygen gas was set to 300 sccm, and the plasma excitation power was set to 2 kW.

The thickness of the formed protective inorganic layer was 35 nm. Therefore, the ratio t₂/t₁ of the thickness t₂ of the protective inorganic layer to the thickness t₁ of the silicon nitride layer was 3.5.

### Example 8

A gas barrier film was produced in the same manner as in Example 6, except that, in the silicon nitride layer forming step, the supply amount of silane gas was set to 400 sccm, the supply amount of ammonia gas was set to 1200 sccm, the supply amount of hydrogen gas was set to 2000 sccm, and the plasma excitation power was set to 5.5 kW.

The thickness of the formed silicon nitride layer was 92 nm. Therefore, the ratio t₂/t₁ of the thickness t₂ of the protective inorganic layer to the thickness t₁ of the silicon nitride layer was 4.9.

### Example 9

A gas barrier film was produced in the same manner as in Example 8, except that the transport speed was set to 0.25 m/min, and in the silicon nitride layer forming step, the supply amount of silane gas was set to 50 sccm, the supply amount of ammonia gas was set to 150 sccm, the supply amount of hydrogen gas was set to 1000 sccm, and the plasma excitation power was set to 0.8 kW.

The thickness of the formed silicon nitride layer was 20 nm. In addition, the thickness of the formed protective inorganic layer was 930 nm. Therefore, the ratio t₂/t₁ of the thickness t₂ of the protective inorganic layer to the thickness t₁ of the silicon nitride layer was 46.5.

### Example 10

A gas barrier film was produced in the same manner as in Example 9, except that, in the protective inorganic layer forming step, the supply amount of HMDSO was set to 800 sccm, the supply amount of oxygen gas was set to 1200 sccm, and the plasma excitation power was set to 7 kW.

The thickness of the formed protective inorganic layer was 1120 nm. Therefore, the ratio t₂/t₁ of the thickness t₂ of the protective inorganic layer to the thickness t₁ of the silicon nitride layer was 56.0.

### Example 11

A gas barrier film was produced in the same manner as in Example 1, except that, in the silicon nitride layer forming step, the supply amount of silane gas was set to 200 sccm, the supply amount of ammonia gas was set to 1000 sccm, the supply amount of hydrogen gas was set to 1000 sccm, and the plasma excitation power was set to 2.5 kW.

The thickness of the formed silicon nitride layer was 12 nm. Therefore, the ratio t₂/t₁ of the thickness t₂ of the protective inorganic layer to the thickness t₁ of the silicon nitride layer was 6.7.

In addition, the refractive index of the silicon nitride layer was 1.68. Therefore, the difference in refractive index between the silicon nitride layer and the protective inorganic layer was 0.20.

### Example 12

A gas barrier film was produced in the same manner as in Example 1, except that, in the silicon nitride layer forming step, the supply amount of silane gas was set to 200 sccm, the supply amount of ammonia gas was set to 200 sccm, the supply amount of hydrogen gas was set to 1000 sccm, and the plasma excitation power was set to 2.5 kW.

The thickness of the formed silicon nitride layer was 9 nm. Therefore, the ratio t₂/t₁ of the thickness t₂ of the protective inorganic layer to the thickness t₁ of the silicon nitride layer was 8.9.

In addition, the refractive index of the silicon nitride layer was 1.99. Therefore, the difference in refractive index between the silicon nitride layer and the protective inorganic layer was 0.51.

### Example 13

A gas barrier film was produced in the same manner as in Example 1, except that, after the protective inorganic layer forming step, the following hydrogen plasma treatment was performed. In Examples 13 to 15, among three film forming sections in the film forming apparatus as shown in FIG. 4, a silicon nitride layer was formed in the first film forming section, a protective inorganic layer was formed in the second film forming section, and the hydrogen plasma treatment was performed in the third film forming section.

(Hydrogen Plasma Treatment)

In the film forming section on the downstream side of the film forming section for forming the protective inorganic layer, the object Z to be treated (protective inorganic layer) was subjected to a hydrogen plasma treatment. In a case of performing the hydrogen plasma treatment, since the generated vacuum ultraviolet rays promote the modification of the silicon oxide film (since, even in a case where incomplete bonds remain, the bonds are promoted), the silicon oxide film has high density and high refractive index.

As a treatment gas, hydrogen gas (H₂) was used. The gas supply amount was 1000 sccm for hydrogen gas. In addition, the film forming pressure was set to 100 Pa. The plasma excitation power was set to 2.5 kW at a frequency of 13.56 MHz.

The thickness of the formed protective inorganic layer was 75 nm. Therefore, the ratio t₂/t₁ of the thickness t₂ of the protective inorganic layer to the thickness t₁ of the silicon nitride layer was 7.5.

In addition, the refractive index of the protective inorganic layer was 1.62. Therefore, the difference in refractive index between the silicon nitride layer and the protective inorganic layer was 0.18.

### Example 14

A gas barrier film was produced in the same manner as in Example 13, except that, in the silicon nitride layer forming step, the supply amount of silane gas was set to 200 sccm, the supply amount of ammonia gas was set to 800 sccm, the supply amount of hydrogen gas was set to 1000 sccm, and the plasma excitation power was set to 2.5 kW, and in the hydrogen plasma treatment, the supply amount of hydrogen gas was set to 1000 sccm and the plasma excitation power was set to 2.0 kW.

The thickness of the formed silicon nitride layer was 10 nm. In addition, the thickness of the formed protective inorganic layer was 75 nm. Therefore, the ratio t₂/t₁ of the thickness t₂ of the protective inorganic layer to the thickness t₁ of the silicon nitride layer was 7.5.

The refractive index of the formed silicon nitride layer was 1.72. In addition, the refractive index of the protective inorganic layer was 1.58. Therefore, the difference in refractive index between the silicon nitride layer and the protective inorganic layer was 0.14.

### Example 15

A gas barrier film was produced in the same manner as in Example 13, except that, in the silicon nitride layer forming step, the supply amount of silane gas was set to 200 sccm, the supply amount of ammonia gas was set to 1000 sccm, the supply amount of hydrogen gas was set to 1000 sccm, and the plasma excitation power was set to 2.5 kW.

The thickness of the formed silicon nitride layer was 10 nm. In addition, the thickness of the formed protective inorganic layer was 75 nm. Therefore, the ratio t₂/t₁ of the thickness t₂ of the protective inorganic layer to the thickness t₁ of the silicon nitride layer was 7.5.

The refractive index of the formed silicon nitride layer was 1.70. In addition, the refractive index of the protective inorganic layer was 1.62. Therefore, the difference in refractive index between the silicon nitride layer and the protective inorganic layer was 0.08.

### Example 16

A gas barrier film was produced in the same manner as in Example 1, except that PET film (manufactured by TOYOBO Co., Ltd., COSMOSHINE A4100; refractive index: 1.54) was used as a substrate and an inorganic base layer was formed according to the following method, instead of the organic base layer. The inorganic base layer was formed on a surface of the substrate on a side not having an easily adhesive layer. In addition, in Example 16, among three film forming sections in the film forming apparatus as shown in FIG. 4, an inorganic base layer was formed in the first film forming section, a silicon nitride layer was formed in the second film forming section, and a protective inorganic layer was formed in the third film forming section.

(Inorganic Base Layer Forming Step)

As a raw material gas for forming the inorganic base layer, hexamethyldisiloxane (HMDSO) gas and oxygen gas (O₂) were used. The gas supply amount was 400 sccm for HMDSO and 600 sccm for oxygen gas. In addition, the film forming pressure was set to 100 Pa. The plasma excitation power was set to 4 kW at a frequency of 13.56 MHz. That is, the inorganic base layer is a silicon oxide film.

The thickness of the formed inorganic base layer was 80 nm.

In addition, the refractive index of the inorganic base layer was 1.48.

### Example 17

A gas barrier film was produced in the same manner as in Example 1, except that, after forming the silicon nitride layer and the silicon oxide layer, the silicon nitride layer and the silicon oxide layer were formed again.

That is, the gas barrier film to be produced is a gas barrier film having, as shown in FIG. 3, a substrate 12, a base layer 14a, a silicon nitride layer 16, a base layer 14b, a silicon nitride layer 16, and a protective inorganic layer 18 in this order. In addition, in the gas barrier film, the base layer 14a is the organic base layer, and the base layer 14b is the inorganic base layer.

### Example 18

In the silicon nitride layer forming step, the supply amount of silane gas was set to 50 sccm, the supply amount of ammonia gas was set to 150 sccm, and the plasma excitation power was set to 0.8 kW. In the protective inorganic layer forming step, the supply amount of HMDSO was set to 40 sccm, the supply amount of oxygen gas was set to 60 sccm, and the plasma excitation power was set to 0.5 kW. A gas barrier film was produced in the same manner as in Example 1 except for these points.

### Example 19

A gas barrier film was produced in the same manner as in Example 5, except that, in the silicon nitride layer forming step, the supply amount of silane gas was set to 25 sccm, the supply amount of ammonia gas was set to 75 sccm, and the plasma excitation power was set to 0.5 kW.

### Example 20

In the silicon nitride layer forming step, the supply amount of silane gas was set to 420 sccm, the supply amount of ammonia gas was set to 1260 sccm, the supply amount of hydrogen gas was set to 2000 sccm, and the plasma excitation power was set to 5 kW.

In the protective inorganic layer forming step, the supply amount of HMDSO was set to 400 sccm, the supply amount of oxygen gas was set to 600 sccm, and the plasma excitation power was set to 4 kW. A gas barrier film was produced in the same manner as in Example 6 except for these points.

### Comparative Example 1

A gas barrier film was produced in the same manner as in Example 1, except that the transport speed was set to 0.25 m/min; in the silicon nitride layer forming step, the supply amount of silane gas was set to 400 sccm, the supply amount of ammonia gas was set to 1200 sccm, the supply amount of hydrogen gas was set to 2000 sccm, and the plasma excitation power was set to 5 kW; and in the protective inorganic layer forming step, the supply amount of HMDSO was set to 50 sccm, the supply amount of oxygen gas was set to 75 sccm, and the plasma excitation power was set to 0.5 kW.

The thickness of the formed silicon nitride layer was 160 nm. In addition, the thickness of the formed protective inorganic layer was 80 nm. Therefore, the ratio t₂/t₁ of the thickness t₂ of the protective inorganic layer to the thickness t₁ of the silicon nitride layer was 0.5.

### Comparative Example 2

A gas barrier film was produced in the same manner as in Example 6, except that, in the protective inorganic layer forming step, the supply amount of HMDSO was set to 700 sccm, the supply amount of oxygen gas was set to 1050 sccm, and the plasma excitation power was set to 6.5 kW.

The thickness of the formed protective inorganic layer was 550 nm. Therefore, the ratio t₂/t₁ of the thickness t₂ of the protective inorganic layer to the thickness t₁ of the silicon nitride layer was 91.7.

### Comparative Example 3

A gas barrier film was produced in the same manner as in Example 7, except that, in the protective inorganic layer forming step, the supply amount of HMDSO was set to 150 sccm, the supply amount of oxygen gas was set to 225 sccm, and the plasma excitation power was set to 1.5 kW.

The thickness of the formed protective inorganic layer was 27 nm. Therefore, the ratio t₂/t₁ of the thickness t₂ of the protective inorganic layer to the thickness t₁ of the silicon nitride layer was 2.7.

### Comparative Example 4

A gas barrier film was produced in the same manner as in Example 8, except that, in the silicon nitride layer forming step, the supply amount of silane gas was set to 450 sccm, the supply amount of ammonia gas was set to 1350 sccm, the supply amount of hydrogen gas was set to 2000 sccm, and the plasma excitation power was set to 5.5 kW.

The thickness of the formed silicon nitride layer was 105 nm. Therefore, the ratio t₂/t₁ of the thickness t₂ of the protective inorganic layer to the thickness t₁ of the silicon nitride layer was 4.3.

<Evaluation>

Gas barrier property (water vapor transmission rate (WVTR)), transparency (total light transmittance), and bending resistance of the produced gas barrier films of Examples and Comparative Examples were evaluated.

(Gas Barrier Property)

Gas barrier property was evaluated by measuring a water vapor transmission rate (WVTR) [g/(m²·day)] according to a calcium corrosion method (method described in JP2005-283561A).

(Transparency)

Transparency was evaluated by measuring total light transmittance using NDH5000 manufactured by NIPPON DENSHOKU INDUSTRIES Co., LTD. in accordance with JIS K 7361-1 (1997).

In a case where the total light transmittance of only the substrate was measured, the total light transmittance of only the substrate was 90%.

(Bending Resistance)

The bending resistance was evaluated by measuring a water vapor transmission rate (WVTR) [g/(m²·day)] after bending the gas barrier film outward at φ8 mm 100000 times, and the evaluation was based on a ratio (WVTR after bending/WVTR before bending) with the water vapor transmission rate before bending. As the value is smaller, bending resistance is higher.

Film forming conditions in each of Examples and Comparative Examples are shown in Table 1, the configurations of the produced gas barrier films are shown in Table 2, and the evaluation results are shown in Table 3.

TABLE 1

| | | Inorganic base | | | Silicon nitride | | | | Protective inorganic | | | | |
|---|---|---|---|---|---|---|---|---|---|---|---|---|---|
| | | layer forming step | | | layer forming step | | | | layer forming step | | | Hydrogen plasma | |
| | | | | | | | | | | | | treatment | |
| | | Gas | | | Gas | | | | Gas | | | Gas | |
| | | flow | | | flow | | | | flow | | | flow | |
| | Transport | rate | | Excitation | rate | | | Excitation | rate | | Excitation | rate | Excitation |
| | speed | HMDSO | O₂ | power | SiH₄ | NH₃ | H₂ | power | HMDSO | O₂ | power | H₂ | power |
| | m/min | sccm | sccm | kW | sccm | sccm | sccm | kW | sccm | sccm | kW | sccm | kW |
| Example 1 | 2 | — | — | — | 200 | 600 | 1000 | 2.5 | 400 | 600 | 4 | — | — |
| Example 2 | 2 | — | — | — | 200 | 600 | 1000 | 2.5 | 400 | 600 | 4 | — | — |
| Example 3 | 2 | — | — | — | 100 | 300 | 1000 | 1.5 | 400 | 600 | 4 | — | — |
| Example 4 | 1 | — | — | — | 100 | 300 | 1000 | 1.5 | 400 | 600 | 4 | — | — |
| Example 5 | 1 | — | — | — | 100 | 300 | 1000 | 2.5 | 600 | 900 | 5.5 | — | — |
| Example 6 | 0.5 | — | — | — | 25 | 75 | 1000 | 0.5 | 600 | 900 | 5.5 | — | — |
| Example 7 | 2 | — | — | — | 200 | 600 | 1000 | 2.5 | 200 | 300 | 2 | — | — |
| Example 8 | 0.5 | — | — | — | 400 | 1200 | 2000 | 5 | 600 | 900 | 5.5 | — | — |
| Example 9 | 0.25 | — | — | — | 50 | 150 | 1000 | 0.8 | 600 | 900 | 5.5 | — | — |
| Example 10 | 0.25 | — | — | — | 50 | 150 | 1000 | 0.8 | 800 | 1200 | 7 | — | — |
| Example 11 | 2 | — | — | — | 200 | 1000 | 1000 | 2.5 | 400 | 600 | 4 | — | — |
| Example 12 | 2 | — | — | — | 200 | 200 | 1000 | 2.5 | 400 | 600 | 4 | — | — |
| Example 13 | 2 | — | — | — | 200 | 600 | 1000 | 2.5 | 400 | 600 | 4 | 1000 | 2.5 |
| Example 14 | 2 | — | — | — | 200 | 800 | 1000 | 2.5 | 400 | 600 | 4 | 1000 | 2 |
| Example 15 | 2 | — | — | — | 200 | 1000 | 1000 | 2.5 | 400 | 600 | 4 | 1000 | 2.5 |
| Example 16 | 2 | 400 | 600 | 4 | 200 | 600 | 1000 | 2.5 | 400 | 600 | 4 | — | — |
| Example 17 | 2 | — | — | — | 200 | 600 | 1000 | 2.5 | 400 | 600 | 4 | — | — |
| | | — | — | — | 200 | 600 | 1000 | 2.5 | 400 | 600 | 4 | — | — |
| Example 18 | 2 | — | — | — | 50 | 150 | 1000 | 0.8 | 40 | 60 | 0.5 | — | — |
| Example 19 | 1 | — | — | — | 25 | 75 | 1000 | 0.5 | 600 | 900 | 5.5 | — | — |
| Example 20 | 0.5 | — | — | — | 420 | 1260 | 2000 | 5 | 400 | 600 | 4 | — | — |
| Comparative | 0.25 | — | — | — | 400 | 1200 | 2000 | 5 | 50 | 75 | 0.5 | — | — |
| Example 1 | | | | | | | | | | | | | |
| Comparative | 0.5 | — | — | — | 25 | 75 | 1000 | 0.5 | 700 | 1050 | 6.5 | — | — |
| Example 2 | | | | | | | | | | | | | |
| Comparative | 2 | — | — | — | 200 | 600 | 1000 | 2.5 | 150 | 225 | 1.5 | — | — |
| Example 3 | | | | | | | | | | | | | |
| Comparative | 0.5 | — | — | — | 450 | 1350 | 2000 | 5.5 | 600 | 900 | 5.5 | — | — |
| Example 4 | | | | | | | | | | | | | |

TABLE 2

| | | Silicon nitride layer | | | Protective inorganic layer | | | | Difference |
|---|---|---|---|---|---|---|---|---|---|
| | | | Thickness | | | Thickness | | Thickness | in |
| | Base | | t₁ | Refractive | | t₂ | Refractive | ratio | refractive |
| | layer | Composition | nm | index | Composition | nm | index | t₂/t₁ | index |
| Example 1 | Organic | SiN | 10 | 1.8 | SiO | 80 | 1.48 | 8.0 | 0.32 |
| Example 2 | None | SiN | 10 | 1.8 | SiO | 80 | 1.48 | 8.0 | 0.32 |
| Example 3 | Organic | SiN | 6 | 1.8 | SiO | 80 | 1.48 | 13.3 | 0.32 |
| Example 4 | Organic | SiN | 10 | 1.8 | SiO | 140 | 1.48 | 14.0 | 0.32 |
| Example 5 | Organic | SiN | 10 | 1.8 | SiO | 240 | 1.48 | 24.0 | 0.32 |
| Example 6 | Organic | SiN | 6 | 1.8 | SiO | 450 | 1.48 | 75.0 | 0.32 |
| Example 7 | Organic | SiN | 10 | 1.8 | SiO | 35 | 1.48 | 3.5 | 0.32 |
| Example 8 | Organic | SiN | 92 | 1.8 | SiO | 450 | 1.48 | 4.9 | 0.32 |
| Example 9 | Organic | SiN | 20 | 1.8 | SiO | 930 | 1.48 | 46.5 | 0.32 |
| Example 10 | Organic | SiN | 20 | 1.8 | SiO | 1120 | 1.48 | 56.0 | 0.32 |
| Example 11 | Organic | SiN | 12 | 1.68 | SiO | 80 | 1.48 | 6.7 | 0.2 |
| Example 12 | Organic | SiN | 9 | 1.99 | SiO | 80 | 1.48 | 8.9 | 0.51 |
| Example 13 | Organic | SiN | 10 | 1.8 | SiO | 75 | 1.62 | 7.5 | 0.18 |
| Example 14 | Organic | SiN | 10 | 1.72 | SiO | 75 | 1.58 | 7.5 | 0.14 |
| Example 15 | Organic | SiN | 10 | 1.7 | SiO | 75 | 1.62 | 7.5 | 0.08 |
| Example 16 | SiO | SiN | 10 | 1.8 | SiO | 80 | 1.48 | 8.0 | 0.32 |
| Example 17 | Organic | SiN | 10 | 1.8 | SiO | 80 | 1.48 | 8.0 | 0.32 |
| | SiO | SiN | 10 | 1.8 | | | | | |
| Example 18 | Organic | SiN | 3 | 1.8 | SiO | 9 | 1.48 | 3.0 | 0.32 |
| Example 19 | Organic | SiN | 3 | 1.8 | SiO | 240 | 1.48 | 80.0 | 0.32 |
| Example 20 | Organic | SiN | 100 | 1.8 | SiO | 300 | 1.48 | 3.0 | 0.32 |
| Comparative | Organic | SiN | 160 | 1.8 | SiO | 80 | 1.48 | 0.5 | 0.32 |
| Example 1 | | | | | | | | | |
| Comparative | Organic | SiN | 6 | 1.8 | SiO | 550 | 1.48 | 91.7 | 0.32 |
| Example 2 | | | | | | | | | |
| Comparative | Organic | SiN | 10 | 1.8 | SiO | 27 | 1.48 | 2.7 | 0.32 |
| Example 3 | | | | | | | | | |
| Comparative | Organic | SiN | 105 | 1.8 | SiO | 450 | 1.48 | 4.3 | 0.32 |
| Example 4 | | | | | | | | | |

TABLE 3

| | Evaluation | | |
|---|---|---|---|
| | Gas barrier property | Transparency | |
| | WVTR | Total light | Bending |
| | g/(m² · day) | transmittance % | resistance |
| Example 1 | 2.00E−05 | 88 | 1.1 |
| Example 2 | 1.10E−04 | 88 | 1.1 |
| Example 3 | 2.50E−05 | 89 | 1.1 |
| Example 4 | 2.00E−05 | 88 | 1.2 |
| Example 5 | 1.90E−05 | 88 | 1.2 |
| Example 6 | 2.20E−05 | 89 | 3.5 |
| Example 7 | 2.00E−05 | 86 | 1.3 |
| Example 8 | 1.70E−05 | 82 | 3.1 |
| Example 9 | 2.00E−05 | 86 | 2.7 |
| Example 10 | 2.00E−05 | 84 | 3.1 |
| Example 11 | 6.00E−05 | 83 | 1.4 |
| Example 12 | 2.50E−05 | 84 | 2.4 |
| Example 13 | 1.80E−05 | 81 | 7.8 |
| Example 14 | 1.80E−05 | 86 | 4.1 |
| Example 15 | 1.80E−05 | 80 | 6.1 |
| Example 16 | 2.00E−05 | 88 | 3.8 |
| Example 17 | 5.00E−06 | 86 | 4 |
| Example 18 | 3.10E−05 | 80 | 1.1 |
| Example 19 | 3.10E−05 | 89 | 7.8 |
| Example 20 | 1.60E−05 | 80 | 7.9 |
| Comparative | 2.20E−05 | 77 | 126 |
| Example 1 | | | |
| Comparative | 2.10E−05 | 88 | 10.2 |
| Example 2 | | | |
| Comparative | 2.10E−05 | 79 | 1.4 |
| Example 3 | | | |
| Comparative | 1.70E−05 | 79 | 10.5 |
| Example 4 | | | |

As shown in Tables 1 to 3, compared with Comparative Examples, it is found that the gas barrier film according to the embodiment of the present invention, in which the protective inorganic layer is formed of silicon oxide, the thickness of the silicon nitride layer is 3 nm to 100 nm, and the ratio t₂/t₁ of the thickness t₂ of the protective inorganic layer to the thickness t₁ of the silicon nitride layer is 3 to 80, has high transparency and excellent bending resistance.

In contrast, Comparative Example 1 in which the silicon nitride layer is thicker than the protective inorganic layer has low transparency and poor bending resistance. In addition, from Comparative Example 2, it is found that, in a case where the ratio t₂/t₁ of the thickness t₂ of the protective inorganic layer to the thickness t₁ of the silicon nitride layer is too large, bending resistance is poor. In addition, from Comparative Example 3, it is found that, in a case where the ratio t₂/t₁ of the thicknesses is too small, transparency is low. In addition, from Comparative Example 4, it is found that, in a case where the silicon nitride layer is too thick, transparency is low and bending resistance is poor.

From the comparison between Example 1 and Example 2, it is found that it is preferable to have the base layer.

From the comparison of Examples 1 and 3 to 10, it is found that the ratio t₂/t₁ of the thicknesses is preferably 6 to 25.

From the comparison between Example 6 and Example 8, it is found that the thickness of the silicon nitride layer is preferably 50 nm or less.

From the comparison between Example 9 and Example 10, it is found that the protective inorganic layer preferably has a thickness of 1000 nm or less.

From the comparison of Examples 1 and 11 to 15, it is found that the difference in refractive index is preferably 0.1 or more.

From the comparison between Example 1 and Example 17, it is found that, by having two or more combinations of the base layer and the silicon nitride layer, gas barrier property is further enhanced.

From the above results, the effect of the present invention is clear.

The present invention can be suitably used as a sealing material for organic EL elements, solar cells, and the like.

### EXPLANATION OF REFERENCES

10, 10a to 10c: gas barrier film

12: substrate

14, 14a and 14b: base layer

16: silicon nitride layer

18: protective inorganic layer

36: laminate roll

50: film forming apparatus

52: vacuum chamber

52a: inner wall surface

54: unwinding section

56a to 56d: partition wall

58, 76, 86, 96: vacuum exhaust unit

60: drum

62: rotating shaft

63a and 63b: guide roller

64: winding shaft

68: bias power supply

70, 80, 90: film forming electrode

72, 82, 92: high-frequency power supply

74, 84, 94: raw material gas supply unit

78: first film forming section

88: second film forming section

98: third film forming section

Z: object to be treated

What is claimed is:

1. A gas barrier film comprising:
a substrate;
a silicon nitride layer; and
a protective inorganic layer disposed on a surface side of the silicon nitride layer, which is opposite to a substrate side of the silicon nitride layer,
wherein the protective inorganic layer is formed of silicon oxide,
a thickness of the silicon nitride layer is 3 nm to 100 nm, and
a ratio t₂/t₁ of a thickness t₂ of the protective inorganic layer to a thickness t₁ of the silicon nitride layer is 3 to 80.

2. The gas barrier film according to claim 1,
wherein a refractive index of the silicon nitride layer is higher than a refractive index of the protective inorganic layer.

3. The gas barrier film according to claim 1,
wherein a difference between a refractive index of the silicon nitride layer and a refractive index of the protective inorganic layer is 0.1 to 0.5.

4. The gas barrier film according to claim 1,
wherein the thickness of the protective inorganic layer is 10 nm to 1000 nm.

5. The gas barrier film according to claim 3,
wherein the thickness of the protective inorganic layer is 10 nm to 1000 nm.

6. The gas barrier film according to claim 1,
wherein the thickness of the silicon nitride layer is 3 nm to 50 nm.

7. The gas barrier film according to claim 3,
wherein the thickness of the silicon nitride layer is 3 nm to 50 nm.

8. The gas barrier film according to claim 4,
wherein the thickness of the silicon nitride layer is 3 nm to 50 nm.

9. The gas barrier film according to claim 1,
wherein a refractive index of the silicon nitride layer is 1.7 to 2.2.

10. The gas barrier film according to claim 3,
wherein the refractive index of the silicon nitride layer is 1.7 to 2.2.

11. The gas barrier film according to claim 6,
wherein a refractive index of the silicon nitride layer is 1.7 to 2.2.

12. The gas barrier film according to claim 1,
wherein a refractive index of the protective inorganic layer is 1.3 to 1.6.

13. The gas barrier film according to claim 3,
wherein the refractive index of the protective inorganic layer is 1.3 to 1.6.

14. The gas barrier film according to claim 9,
wherein a refractive index of the protective inorganic layer is 1.3 to 1.6.

15. The gas barrier film according to claim 1,
wherein the protective inorganic layer includes carbon, and
the content of the carbon is 2 atom % to 20 atom %.

16. The gas barrier film according to claim 1, further comprising:
a base layer disposed on the substrate side of the silicon nitride layer.

17. The gas barrier film according to claim 16,
wherein the base layer is formed of an inorganic material having a refractive index lower than that of the silicon nitride layer.

18. The gas barrier film according to claim 19,
wherein the base layer is formed of silicon oxide.

19. A gas barrier film comprising:
a substrate;
a silicon nitride layer; and
a protective inorganic layer disposed on a surface side of the silicon nitride layer, which is opposite to a substrate side of the silicon nitride layer,
a base layer disposed on the substrate side of the silicon nitride layer,
wherein
the protective inorganic layer and the base layer are formed of silicon oxide,
the thickness of the protective inorganic layer is 10 nm to 1000 nm,
the thickness of the silicon nitride layer is 3 nm to 50 nm,
the refractive index of the silicon nitride layer is 1.7 to 2.2,
the refractive index of the protective inorganic layer is 1.3 to 1.6,
the content of the carbon is 2 atom % to 20 atom %,
the base layer is formed of silicon oxide having a refractive index lower than that of the silicon nitride layer, and
a ratio t₂/t₁ of a thickness t₂ of the protective inorganic layer to a thickness t₁ of the silicon nitride layer is 3 to 80.
